(19) United States
(12) Patent Application Publication
(10) Pub. No.: US 2024/0389279 A1
(43) Pub. Date: Nov. 21, 2024

(54) ELECTRONIC CONTROL APPARATUS AND ELECTRIC BRAKE APPARATUS

(71) Applicant: Hitachi Astemo, Ltd., Hitachinaka-shi, Ibaraki (JP)

(72) Inventors: Tomohiro UCHIDA, Hitachinaka-shi, Ibaraki (JP); Haruhiko FUJITA, Hitachinaka-shi, Ibaraki (JP)

(21) Appl. No.: 18/691,576

(22) PCT Filed: Nov. 22, 2022
(86) PCT No.: PCT/JP2022/043130

§ 371 Date: Mar. 13, 2024

(30) Foreign Application Priority Data
Dec. 21, 2021 (JP) 2021-207112

(51) Int. Cl. H05K 7/20; F16D 55/226; F16D 65/18; F16D 121/24; H02K 11/33; H05K 1/18

(52) U.S. Cl. CPC H05K 7/209; F16D 55/226; F16D 65/18; H02K 11/33; H05K 1/181; F16D 2121/24

(57) ABSTRACT

An electronic control apparatus includes a control board, a heat-generating electronic component mounted on the control board, and a heat sink provided with a heat dissipation material interposed between the heat sink and the heat-generating electronic component. The heat sink includes at least a distal-side abutment portion in abutment with the control board at a position away from the heat-generating electronic component, and first and second proximal-side abutment portions in abutment with the control board without being fixed to the control board at positions away from the heat-generating electronic component by distances shorter than a distance between the heat-generating electronic component and the distal-side abutment portion. Due to that, the impairment of the heat dissipation performance can be reduced.

### TECHNICAL FIELD

The present invention relates to an electronic control apparatus and an electric brake apparatus.

### BACKGROUND ART

PTL 1 discloses an electronic device including a heat sink, where heat dissipating gel is interposed between the heat sink and a side of an electronic component, which is mounted on a substrate. The electronic component includes an electrical conductor electrically connected to a chip, and an insulator portion that molds the chip with the electrical conductor. The heat sink includes a non-abutting surface that faces the electrical conductor of the electronic component, the heat dissipating gel interposed between the non-abutting surface and the electrical conductor, and an abutting surface that is positioned closer toward the substrate than the non-abutting surface is and abuttable with the insulator portion.

### CITATION LIST

### Patent Literature

PTL 1: Japanese Patent Application Laid-Open No. 2016-33958

### SUMMARY OF INVENTION

### Technical Problem

However, in the electronic device discussed in PTL 1, the substrate is fixed to the heat sink using screw members threadedly engaged with screw holes formed on a support portion of the heat sink, and this raises the necessity of providing holes for the screw members and seat surfaces for the screw members, thereby making it difficult to position an abutment portion of the heat sink with the substrate close to the electronic component and requiring the abutment portion of the heat sink with the substrate to be arranged a predetermined distance away. Then, when the abutment portion of the heat sink with the substrate is undesirably located away from the electronic component, a variation may occur in the thickness of the heat dissipating material interposed between the electronic component and the heat sink, resulting in the impairment of the heat dissipation performance.

Under these circumstances, one of objects of the present invention is to provide an electronic control apparatus and an electric brake apparatus capable of reducing the impairment of the heat dissipation performance.

### Solution to Problem

As a solution to the above-described problem, an electronic control apparatus according to the present invention includes a board, an electronic component mounted on the board, and a heat sink provided with a heat dissipation material interposed between the heat sink and the electronic component. The heat sink includes at least a distal-side abutment portion in abutment with the board at a position away from the electronic component, and a proximal-side abutment portion in abutment with the board without being fixed to the board at a position away from the electronic component by a distance shorter than a distance between the electronic component and the distal-side abutment portion.

Further, an electric brake apparatus according to the present invention includes an electric motor configured to provide power for pressing a frictional pad against a rotor that rotates together with a wheel, and an electronic control apparatus configured to control driving of the electric motor. The electronic control apparatus includes a board, an electronic component mounted on the board, and a heat sink provided with a heat dissipation material interposed between the heat sink and the electronic component. The heat sink includes at least a distal-side abutment portion in abutment with the board at a position away from the electronic component, and a proximal-side abutment portion unfixedly provided in abutment with the board at a position away from the electronic component by a distance shorter than a distance between the electronic component and the distal-side abutment portion.

According to one aspect of the present invention, the impairment of the heat dissipation performance can be reduced.

### BRIEF DESCRIPTION OF DRAWINGS

FIG. 1 is a cross-sectional view of a disk brake according to an embodiment of the present invention.

FIG. 2 is an enlarged view of an A portion in FIG. 1.

FIG. 3 is an exploded perspective view of a control portion housing including a heat sink, a control board, and a motor gear housing, which is employed in the disk brake according to the embodiment of the present invention.

FIG. 4 is a plan view of the control portion housing employed in the disk brake according to the embodiment of the present invention.

FIG. 5 is a plan view of an opposite-end surface of the heat sink employed in the disk brake according to the embodiment of the present invention.

FIG. 6 is a plan view of the control board employed in the disk brake according to the embodiment of the present invention.

FIG. 7 is a side view of the control board employed in the disk brake according to the embodiment of the present invention.

FIG. 8 illustrates the relationship between the thickness of a heat dissipation material and a change in the temperature of a heat-generating electronic component employed in the disk brake according to the embodiment of the present invention.

FIG. 9 illustrates the relationship between the thickness of the heat dissipation material and the distance between the heat-generating electronic component and a proximal-side abutment portion employed in the disk brake according to the embodiment of the present invention.

FIG. 10 is a cross-sectional view of a configuration similar to FIG. 2 that illustrates a control board according to another embodiment.

FIG. 11 is a plan view of the opposite-end surface of the heat sink that illustrates an abutment portion of the heat sink according to another embodiment.

FIG. 12 is a plan view of the opposite-end surface of the heat sink that illustrates an abutment portion of the heat sink according to further another embodiment.

FIG. 13 is a plan view of the opposite-end surface of the heat sink that illustrates an abutment portion of the heat sink according to further another embodiment.

FIG. 14 is a plan view of the opposite-end surface of the heat sink that illustrates an abutment portion of the heat sink according to further another embodiment.

### DESCRIPTION OF EMBODIMENTS

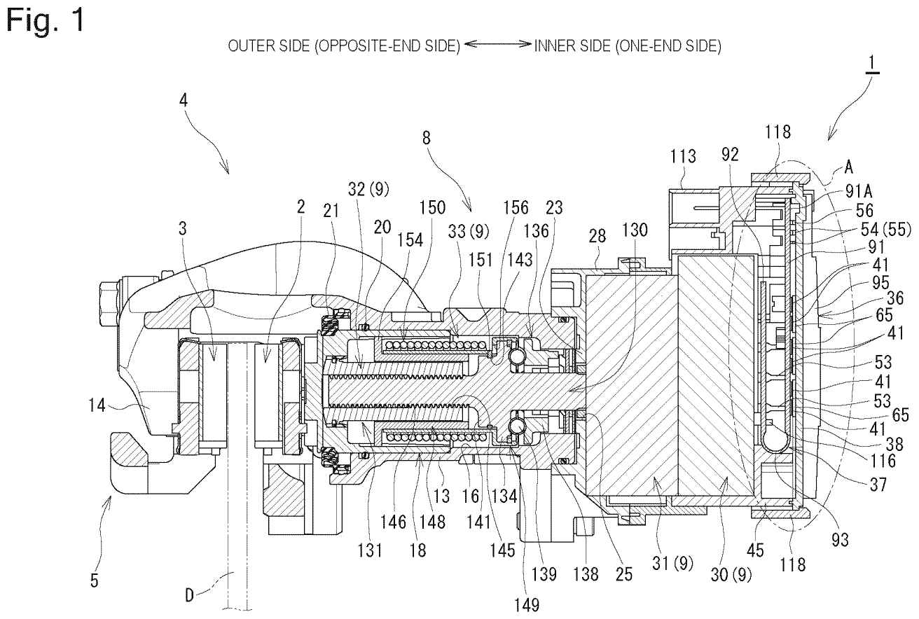

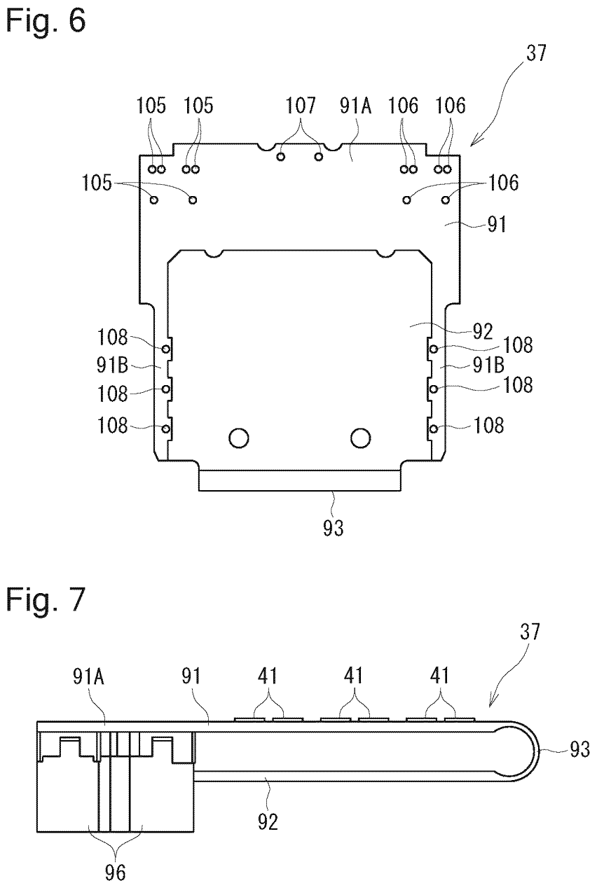

In the following description, embodiments of the present invention will be described in detail with reference to FIGS. 1 to 14.

A disk brake 1 according to each of the embodiments of the present invention is an electric brake apparatus that generates a braking force based on driving of an electric motor 30 while a vehicle runs normally. In the following description, the present embodiment will be described, referring to the internal side of the vehicle (the inner side) as a one-end side (a heat sink 38 side), and the external side of the vehicle (the outer side) as an opposite-end side (a disk rotor D side) as necessary.

Referring to FIG. 1, the disk brake 1 according to the present embodiment includes a pair of inner and outer brake pads 2 and 3 and a caliper 4. The pair of inner and outer brake pads 2 and 3 is disposed on both the axial sides of a disk rotor D. The disk rotor D is mounted at a rotational portion of the vehicle. The present disk brake 1 is configured as a floating caliper-type disk brake. The pair of inner and outer brake pads 2 and 3, and the caliper 4 are supported on a carrier 5 movably in the axial direction of the disk rotor D. The carrier 5 is fixed to a non-rotational portion such as a knuckle of the vehicle. The disk rotor D corresponds to a rotor. Further, the inner brake pad 2 and the outer brake pad 3 correspond to a frictional pad.

Referring to FIG. 1, the caliper 4 includes a caliper main body 8 and a drive unit 9. The caliper main body 8 constitutes the main body of the caliper 4. The drive unit 9 provides power to press the inner brake pad 2 and the outer brake pad 3 against the disk rotor D. The caliper main body 8 includes a cylindrical cylinder portion 13 and a pair of claw portions 14 and 14. The cylinder portion 13 is disposed on the proximal end side facing the inner brake pad 2, and is opened while facing this inner brake pad 2. The pair of claw portions 14 and 14 extend from the cylinder portion 13 to the outer side across over the disk rotor D, and is disposed on the distal end side (the opposite-end side) facing the outer brake pad 3. FIG. 1 illustrates only one of the pair of claw portions 14 and 14.

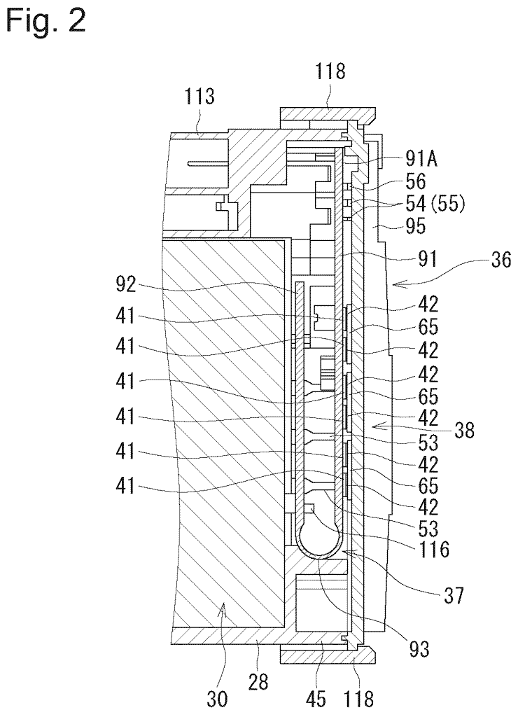

Referring to FIGS. 1 and 2, a piston 18 is contained non-rotatably and axially movably relative to the cylinder portion 13 inside the cylinder portion 13 of the caliper main body 8, i.e., in a cylinder bore 16 of the cylinder portion 13. The piston 18 functions to press the inner brake pad 2, and is formed into a bottomed cupped shape. This piston 18 is contained in the cylinder bore 16 in such a manner that the bottom portion thereof faces the inner brake pad 2. The piston 18 is supported non-rotatably relative to the cylinder bore 16 of the cylinder portion 13 and thus the caliper main body 8 due to engagement prohibiting a rotation between the bottom portion of the piston 18 and the inner brake pad 2, such as recess-protrusion engagement.

Referring to FIG. 1, a seal member 20 is disposed in the cylinder bore 16 of the cylinder portion 13 on the inner peripheral surface on the opposite-end side thereof. Then, the piston 18 is contained in the cylinder bore 16 axially movably in a state of being in contact with this seal member 20. A dust boot 21 is interposed between the outer wall portion of the piston 18 on the bottom-portion side thereof and the inner peripheral surface of the cylinder bore 16 on the opposite-end side thereof having an increased diameter. The disk brake 1 is configured to prevent an entry of a foreign object into the cylinder bore 16 of the cylinder portion 13 with the aid of these seal member 20 and dust boot 21.

A motor/gear housing 28 is integrally coupled with a bottom wall 23 side (the one-end side) of the cylinder portion 13. An insertion hole 25 is provided on the bottom wall 23 of the cylinder portion 13, and a spindle 130, which will be described below, extends into the motor/gear housing 28 via this insertion hole 25. The drive unit 9 is disposed in the motor/gear housing 28, and the cylinder bore 16 of the cylinder portion 13. The drive unit 9 functions to transmit a rotation input from the electric motor 30 to the piston 18 contained in the cylinder bore 16 of the cylinder portion 13 and press the inner brake pad 2 and the outer brake pad 3 against the disk rotor D using the thrust force of this piston 18.

Referring to FIG. 1, the drive unit 9 includes the electric motor 30, a speed reduction gear mechanism 31, a rotation-linear motion conversion mechanism 32, and a fail-open mechanism 33. The rotation input from the electric motor 30 is transmitted to the speed reduction gear mechanism 31, and the speed reduction gear mechanism 31 powers up the rotational torque input from this electric motor 30. The rotation-linear motion conversion mechanism 32 converts a rotation input from this speed reduction gear mechanism 31 into a linear motion, and provides the thrust force to the piston 18. While the vehicle is braked, the fail-open mechanism 33 releases this braking force when the electric motor 30 cannot be driven normally due to a failure in a power source or the like. The driving of the electric motor 30 is controlled according to an instruction from a control board 37 of an electronic control apparatus 36. The electric motor 30 and the speed reduction gear mechanism 31 are disposed in the motor/gear housing 28.

The speed reduction gear mechanism 31 functions to power up the rotational torque input from the electric motor 30 and transmit it to the rotation-linear motion conversion mechanism 32. This speed reduction gear mechanism 31 is housed in the motor/gear housing 28 and on the opposite-end side (the cylinder portion 13 side) with respect to the electric motor 30. For example, a planetary gear speed reduction mechanism is employed as this speed reduction gear mechanism 31. The electronic control apparatus 36 includes the control board 37 and a heat sink 38. A heat-generating electronic component 41 is mounted on the control board 37. The heat sink 38 is provided with a heat dissipation material 42 interposed between the heat sink 38 and the heat-generating electronic component 41 mounted on this control board 37. The heat-generating electronic component 41 corresponds to an electronic component.

The control board 37 functions to control the rotation of the electric motor 30 (a rotational direction, a rotational speed, and the like) based on various detection signals, such as a detection signal from a detection sensor that responds to a request from a driver or a detection sensor that detects various situations requiring the brake, a wheel speed detection sensor that detects a wheel speed, a detection signal from a rotational angle detector (not illustrated) that detects a rotational angle of a rotational shaft (not illustrated) of the electric motor 30, and a detection signal from a thrust force sensor (not illustrated) or the like that detects a thrust force (a pressing force) applied from the inner and outer brake pads 2 and 3 to the disk rotor D at the time of braking while the vehicle runs normally.

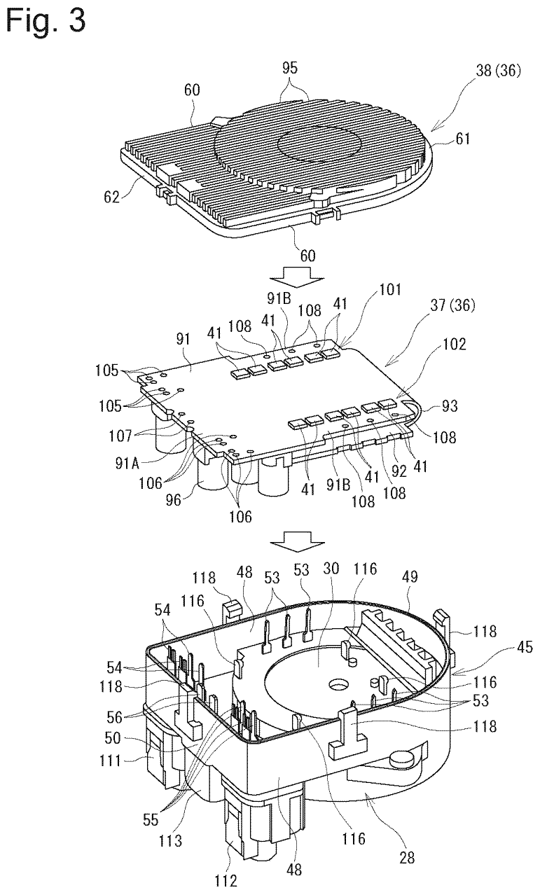

The control board 37 is disposed on the one-end side with respect to the electric motor 30. In other words, the electric motor 30 is disposed so as to be interposed between the control board 37 including the heat-generating electronic component 41 of the electronic control apparatus 36 and the speed reduction gear mechanism 31 along the axial direction of the rotational shaft of the electric motor 30. The control board 37 including the heat-generating electronic component 41 is housed in a control portion housing 45. Also referring to FIG. 3, the control portion housing 45 is integrally connected to the motor/gear housing 28. The control portion housing 45 is disposed on the one-end side continuously from the motor/gear housing 28, i.e., disposed opposite from the disk rotor D. The control portion housing 45 is provided in a manner protruding beyond the motor/gear housing 28 outward in the radial direction of the disk rotor D. The control portion housing 45 is provided in a manner protruding beyond the motor/gear housing 28 to one side closer to base portions of the claw portions 14 and 14. The heat sink 38 is provided on the opening of the control portion housing 45 on the one-end side. The heat sink 38 functions to air-tightly close this opening and also enhance an effect of dissipating heat generated from the control board 37 (the heat-generating electronic component 41).

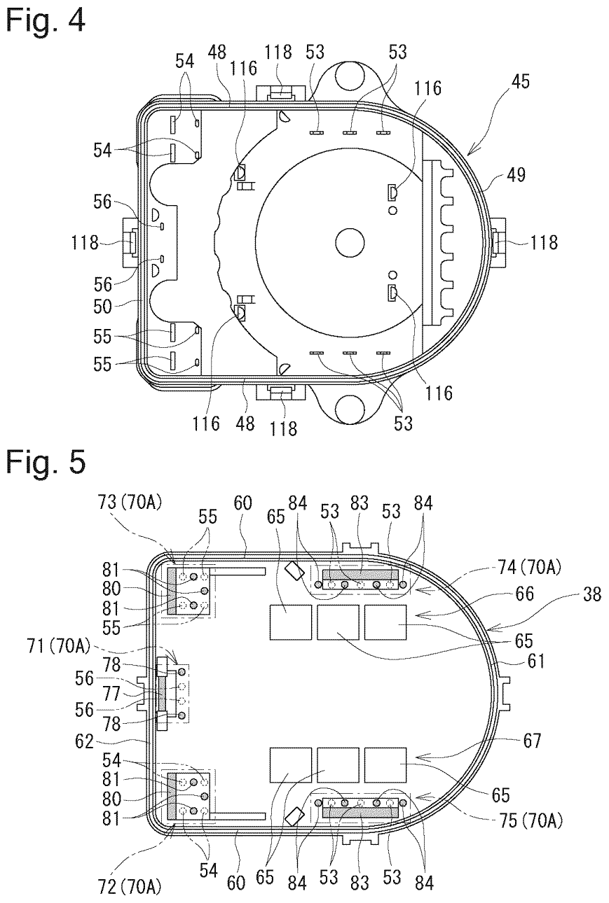

Referring to FIGS. 1 and 3, a wall portion of the control portion housing 45 on the central side in the radial direction of the disk rotor D is curved in a circular-arc shape. In sum, referring to FIG. 3, the control portion housing 45 is formed by being surrounded by a pair of opposite linear wall portions 48 and 48, a curved wall portion 49, and a main linear wall portion 50. The opposite linear wall portions 48 and 48 are located opposite from each other. The curved wall portion 49 extends in a circular-arc shape. The main linear wall portion 50 is located opposite from the curved wall portion 49. As illustrated in FIGS. 3 and 4, a large number of various types of terminals extend toward the one-end side in the control portion housing 45. More specifically, a motor terminal 53, a first connector terminal 54, a second connector terminal 55, and a third connector terminal 56 are disposed in the control portion housing 45 as the various types of terminals. A plurality of motor terminals 53 is disposed along one of the opposite linear wall portions 48, and close to this opposite linear wall portion 48 and at intervals in series. In the present embodiment, three motor terminals 53 are disposed on the one opposite linear wall portion 48 side. Further, a plurality of motor terminals 53 is disposed along the other of the opposite linear wall portions 48, and close to this opposite linear wall portion 48 and at intervals in series. In the present embodiment, three motor terminals 53 are disposed on the other opposite linear wall portion 48 side. In the above-described manner, the plurality of motor terminals 53 electrically connected to the electric motor 30 extends in the control portion housing 45.

A plurality of first connector terminals 54 is disposed at intervals at corner portions between the main linear wall portion 50 and the end portion of the one of the opposite linear wall portions 48 of the control portion housing 45. In the present embodiment, four first connector terminals 54 are disposed so as to be located at four corners of a rectangle, respectively. A plurality of second connector terminals 55 is disposed at intervals at corner portions between the main linear wall portion 50 and the end portion of the other of the opposite linear wall portions 48 of the control portion housing 45. In the present embodiment, four second connector terminals 55 are disposed so as to be located at four corners of a rectangle, respectively. A plurality of third connector terminals 56 is disposed at the center of the main linear wall portion 50 of the control portion housing 45, and close to this main linear wall portion 50 and at intervals. In the present embodiment, two third connector terminals 56 are disposed along the main linear wall portion 50 at an interval from each other.

Referring to FIGS. 1 and 3, the opening of the control portion housing 45 on the one-end side is closed by the heat sink 38 as described above. A highly thermally conductive material, such as an aluminum material, is employed for the heat sink 38. The heat sink 38 is formed into a plate-like shape. Similarly to the outer shape of the opening of the control portion housing 45 on the one-end side, the heat sink 38 includes a pair of opposite linear portions 60 and 60 located opposite from each other, a curved portion 61 extending in a circular-arc shape, and a main linear portion 62 located opposite from the curved portion 61.

Referring to FIGS. 3 and 5, component corresponding portions 65 are formed on the opposite-end surface of the heat sink 38 at positions corresponding to a plurality of heat-generating electronic components 41 on a first board portion 91, which will be described below, respectively. Each of the component corresponding portions 65 is provided in a manner protruding from the opposite-end surface of the heat sink 38 toward inside the control portion housing 45. In the present embodiment, one component corresponding portion 65 is formed in correspondence with two heat-generating electronic components 41. In other words, a pair of first and second component corresponding portion lines 66 and 67 is formed on the opposite-end surface of the heat sink 38 in parallel with each other. Three component corresponding portions 65 are disposed at intervals in series in each of the first and second component corresponding portion lines 66 and 67. The first and second component corresponding portion lines 66 and 67 extend along the opposite linear portions 60 and 60 of the heat sink 38. The first and second component corresponding portion lines 66 and 67 are formed at positions slightly offset toward the pair of opposite linear portion 60 and 60 sides of the heat sink 38, respectively. A plurality of abutment portions 70A is formed on the opposite-end surface of the heat sink 38. The abutment portions 70A are in abutment with the first board portion 91 of the control board 37. The abutment portions 70A are provided in a manner protruding from the opposite-end surface of the heat sink 38 toward inside the control portion housing 45.

The abutment portions 70A include a distal-side abutment portion 71, first and second intermediate abutment portions 72 and 73, and first and second proximal-side abutment portions 74 and 75. The distal-side abutment portion 71 is disposed at a position away from the first and second component corresponding portion lines 66 and 67 (first and second heat-generating electronic component lines 101 and 102). The distal-side abutment portion 71 is located at an approximately central position of the main linear portion 62 of the heat sink 38. The distal-side abutment portion 71 includes a rectangular abutment portion 77 (a light black-filled portion in FIG. 5) and a plurality of circular abutment portions 78 (light black-filled portions in FIG. 5). The rectangular abutment portion 77 is generally rectangular in a planar view. The plurality of circular abutment portions 78 is disposed on the curved portion 61 side of the heat sink 38 with respect to this rectangular abutment portion 77, and is generally circular in a planar view.

The rectangular abutment portion 77 extends along the main linear portion 62 of the heat sink 38, and is disposed close to this main linear portion 62. The plurality of circular abutment portions 78 is disposed at intervals on the curved portion 61 side of the heat sink 38 with respect to the rectangular abutment portion 77. The plurality of circular abutment portions 78 is disposed at intervals along the main linear portion 62 of the heat sink 38. In the present embodiment, two circular abutment portions 78 are formed. A plurality of connector terminals 56 and 56 is located between the adjacent circular abutment portions 78 and 78. In the present embodiment, two third connector terminals 56 and 56 are located in the distal-side abutment portion 71. In FIG. 5, the third connector terminals 56 are indicated by long dashed double-short dashed lines.

The first and second intermediate abutment portions 72 and 73 are disposed at positions spaced apart from the first and second component corresponding portion lines 66 and 67 (the first and second heat-generating electronic component lines 101 and 102) by distances shorter than the distance between the first or second component corresponding portion line 66 or 67 and the distal-side abutment portion 71, respectively. The first and second intermediate abutment portions 72 and 73 are disposed on the both sides of the distal-side abutment portion 71 and at the respective corner portions between the both end portions of the main linear portion 62 of the heat sink 38 and the end portions of the pair of opposite linear portions 60 and 60. Each of the first and second intermediate abutment portions 72 and 73 includes a rectangular abutment portion 80 (a light black-filled portion in FIG. 5) and a plurality of circular abutment portions 81 (light black-filled portions in FIG. 5). The rectangular abutment portion 80 is generally rectangular in a planar view. The plurality of circular abutment portions 81 is disposed on the curved portion 61 side of the heat sink 38 with respect to this rectangular abutment portion 80, and is generally circular in a planar view.

The rectangular abutment portion 80 extends along the main linear portion 62 of the heat sink 38, and is disposed close to this main linear portion 62. The plurality of circular abutment portions 81 is disposed at intervals on the curved portion 61 side of the heat sink 38 with respect to the rectangular abutment portion 80. In the present embodiment, the circular abutment portions 81 are disposed at three portions, respectively, in such a manner that a line connecting centers thereof defines a triangular shape. A plurality of first or second connector terminals 54 or 55 is disposed around these circular abutment portions 81. In the present embodiment, four first or second connector terminals 54 or 55 are located in the first or second intermediate abutment portion 72 or 73. In FIG. 5, the first and second connector terminals 54 and 55 are indicated by long dashed double-short dashed lines.

The first and second proximal-side abutment portions 74 and 75 are disposed at positions spaced apart from the first and second component corresponding portion lines 66 and 67 (the first and second heat-generating electronic component lines 101 and 102) by distances shorter than the distance between the first or second component corresponding portion line 66 or 67 and the first or second intermediate abutment portion 72 or 73, respectively. Each of the first and second proximal-side abutment portions 74 and 75 is disposed between the first or second component corresponding portion line 66 or 67 and the one or the other of the opposite linear portions 60 of the heat sink 38. More specifically, the first proximal-side abutment portion 74 is disposed between the first component corresponding portion line 66 and the one of the opposite linear portions 60 of the heat sink 38. The second proximal-side abutment portion 75 is disposed between the second component corresponding portion line 67 and the other of the opposite linear portions 60 of the heat sink 38. Each of the first and second proximal-side abutment portions 74 and 75 includes a rectangular abutment portion 83 (a light black-filled portion in FIG. 5) and a plurality of circular abutment portions 84 (light black-filled portions in FIG. 5). The rectangular abutment portion 83 is generally rectangular in a planar view. The plurality of circular abutment portions 84 is disposed on the first or second component corresponding portion line 66/67 side with respect to this rectangular abutment portion 83, and is generally circular in a planar view.

The rectangular abutment portion 83 extends along the opposite linear portion 60 of the heat sink 38, and is disposed close to this opposite linear portion 60. The plurality of circular abutment portions 84 is disposed at intervals on the first or second component corresponding portion line 66/67 side with respect to this rectangular abutment portion 83. These circular abutment portions 84 are disposed in alignment at intervals in series along the opposite linear portion 60 of the heat sink 38. In the present embodiment, four circular abutment portions 84 are formed. The motor terminals 53 are each located between the adjacent circular abutment portions 84 and 84. Three motor terminals 53 are located in each of the first and second proximal-side abutment portions 74 and 75. In FIG. 5, the motor terminals 53 are indicated by long dashed double-short dashed lines.

In other words, in the first proximal-side abutment portion 74, each of the motor terminals 53 is located between the rectangular abutment portion 83 and the first component corresponding portion line 66 thereof. In the second proximal-side abutment portion 75, each of the motor terminals 53 is located between the rectangular abutment portion 83 and the second component corresponding portion line 67 thereof. As a result, each of the motor terminals 53 is located between the rectangular abutment portion 83 of the first proximal-side abutment portion 74 and the heat-generating electronic component 41 on the first board portion 91. On the other hand, each of the motor terminals 53 is located between the rectangular abutment portion 83 of the second proximal-side abutment portion 75 and the heat-generating electronic component 41 on the first board portion 91. Further, a plurality of motor terminals 53 (six motor terminals 53) is disposed between the rectangular abutment portion 83 of the first proximal-side abutment portion 74 and the rectangular abutment portion 83 of the second proximal-side abutment portion 75.

In the above-described manner, the distance between the first proximal-side abutment portion 74 and the first component corresponding portion line 66, i.e., the first heat-generating electronic component line 101, and the distance between the second proximal-side abutment portion 75 and the second component corresponding portion line 67, i.e., the second heat-generating electronic component line 102 are approximately equal to each other, and this distance is the shortest. Further, the distance between the distal-side abutment portion 71 and the first component corresponding portion line 66, i.e., the first heat-generating electronic component line 101, and the distance between the distal-side abutment portion 71 and the second component corresponding portion line 67, i.e., the second heat-generating electronic component line 102 are approximately equal to each other, and this distance is the longest.

Further, a part of the first or second component corresponding portion line 66 or 67 is disposed between the first or second proximal-side abutment portion 74 or 75 and the distal-side abutment portion 71. As a result, the heat-generating electronic components 41 on the first board portion 91 of the control board 37 are disposed between the first or second proximal-side abutment portion 74 or 75 and the distal-side abutment portion 71. Referring to FIG. 3, a large number of heat dissipation fins 95 are provided on the outer peripheral surface (the one-end surface) of the heat sink 38. A heat mass (a heat capacity) is secured on the heat sink 38 by increasing the volume thereof, and therefore heat of each of the heat-generating electronic components 41 is efficiently dissipated to outside air by passing through the heat sink 38 side having a large heat mass instead of the control board 37 side having a small heat mass.

Referring to FIGS. 3, 6, and 7, the control board 37 is made of a flexible printed circuit. The control board 37 includes the first board portion 91 and a second board portion 92 formed by folding one long control board into two layers. In other words, the control board 37 includes the first board portion 91, the second board portion 92, and a folded portion 93. The second board portion 92 is disposed so as to face the first board portion 91. The folded portion 93 is provided between the first board portion 91 and the second board portion 92. The first board portion 91 and the second board portion 92 are disposed so as to face each other with a predetermined distance generated therebetween along the axial direction of the disk rotor D. The first board portion 91 and the second board portion 92 are biased in a direction away from each other based on the folded portion 93.

Both the first board portion 91 and the second board portion 92 are formed into approximately rectangular shapes. The first board portion 91 is located on the heat sink 38 side. The second board portion 92 is located on the electric motor 30 side (the disk rotor D side). The folded portion 93 is located on the curved wall portion 49 side of the control portion housing 45. The plurality of heat-generating electronic components 41, such as a semiconductor switching element (MOSFET) and a capacitor, is mounted on the first board portion 91. Each of the heat-generating electronic components 41 is mounted on the surface of the first board portion 91 on the heat sink 38 side. The plurality of first and second heat-generating electronic component lines 101 and 102 is disposed in parallel on the first board portion 91. The plurality of heat-generating electronic components 41 is lined up in each of the first and second heat-generating electronic component lines 101 and 102 at intervals in series. In the present embodiment, two first and second heat-generating electronic component lines 101 and 102 are disposed in parallel on the first board portion 91. Six heat-generating electronic components 41 are lined up in each of the first and second heat-generating electronic component lines 101 and 102 at intervals in series.

Referring to FIGS. 3 and 5, the first heat-generating electronic component line 101 on the first board portion 91 and the first component corresponding portion line 66 of the heat sink 38 correspond to each other, and the second heat-generating electronic component line 102 on the first board portion 91 and the second component corresponding portion line 67 of the heat sink 38 correspond to each other, as described above. In the present embodiment, the six heat-generating electronic components 41 in the first heat-generating electronic component line 101 on the first board portion 91 correspond to the three component corresponding portions 65 in the first component corresponding portion line 66 of the heat sink 38. The six heat-generating electronic components 41 in the second heat-generating electronic component line 102 on the first board portion 91 correspond to the three component corresponding portions 65 in the second component corresponding portion line 67 of the heat sink 38. Then, each of the heat-generating electronic components 41 on the first board portion 91 is placed in close contact with the component corresponding portion 65 of the heat sink 38 corresponding thereto via the heat dissipation material 42. The heat dissipation material 42 is made of a non-fluid or fluid material. A highly thermally dissipative adhesive agent, a heat dissipation sheet, or the like is employed as the non-fluid material. On the other hand, a heat dissipation gel, grease, or the like is employed as the fluid material.

Referring to FIGS. 3, 6, and 7, the first board portion 91 is larger than the second board portion 92 in area. The first board portion 91 protrudes beyond the second board portion 92 along the longitudinal direction thereof toward the main linear wall portion 50 side of the control portion housing 45. In other words, a board protrusion portion 91A is provided on the first board portion 91 at a position where it does not overlap the second board portion 92 on the main linear wall portion 50 side of the control portion housing 45. A tall component 96 such as an electrolytic capacitor longer than a predetermined distance between the first board portion 91 and the second board portion 92 is provided on the board protrusion portion 91A of the first board portion 91. The board protrusion portion 91A of the first board portion 91 is disposed inside a portion of the control portion housing 45 that protrudes beyond the motor/gear housing 28.

A plurality of first connector terminal connection holes 105 is formed on the board protrusion portion 91A of the first board portion 91 on one end side in the width direction thereof. The plurality of first connector terminal connection holes 105 corresponds to the plurality of first connector terminals 54. A plurality of second connector terminal connection holes 106 is formed on the board protrusion portion 91A of the first board portion 91 on an opposite end side in the width direction thereof. The plurality of second connector terminal connection holes 106 corresponds to the plurality of second connector terminals 55. A plurality of third connector terminal connection holes 107 is formed on the board protrusion portion 91A of the first board portion 91 at the center in the width direction thereof. The plurality of third connector terminal connection holes 107 corresponds to the plurality of third connector terminals 56. Further, board protrusion portions 91B and 91B are formed on the first board portion 91. The board protrusion portions 91B and 91B protrude outward beyond the second board portion 92 from the both ends in the width direction, respectively. In other words, the pair of board protrusion portions 91B and 91B is provided on the first board portion 91 at positions where they do not overlap the second board portion 92 along the width direction thereof. A plurality of motor terminal connection holes 108 is formed on each of these board protrusion portions 91B and 91B. The plurality of motor terminal connection holes 108 corresponds to the plurality of motor terminals 53.

The first board portion 91 is electrically connected to the electric motor 30 via each of the motor terminals 53. Each of a first connector 111, a second connector 112, and a third connector 113 is electrically connected to the first board portion 91 and the second board portion 92 of the control board 37. The first connector 111, the second connector 112, and the third connector 113 are disposed at positions where they overlap the board protrusion portion 91A of the first board portion 91 of the electronic control apparatus 36 in the axial direction of the disk rotor D. Referring to FIGS. 1 and 3, the first connector 111, the second connector 112, and the third connector 113 are provided in a manner protruding from the portion of the control portion housing 45 that protrudes beyond the motor/gear housing 28 to the opposite-end side, i.e., the disk rotor D side along the axial direction of the disk rotor D.

The first connector 111, the second connector 112, and the third connector 113 are arranged so as to be lined up in alignment. More specifically, the first connector 111, the second connector 112, and the third connector 113 are arranged so as to be lined up in alignment along the main linear wall portion 50 of the control portion housing 45. The third connector 113 is disposed so as to be interposed between the first connector 111 and the second connector 112. The plurality of first connector terminals 54 extends from the first connector 111 into the control portion housing 45. The plurality of second connector terminals 55 extends from the second connector 112 into the control portion housing 45. The plurality of third connector terminals 56 extends from the third connector 113 into the control portion housing 45. The position of each of these first connector terminals 54, second connector terminals 55, and third connector terminals 56 in the control portion housing 45 has been described above, and therefore the detailed description thereof is omitted here.

Then, referring to FIGS. 1 to 3, the control board 37 is arranged in such a manner that the first board portion 91 and the second board portion 92 overlap each other via the folded portion 93 due to the distal-side abutment portion 71, the first and second intermediate abutment portions 72 and 73, and the first and second proximal-side abutment portions 74 and 75 of the heat sink 38 while resisting the biasing forces thereof with the control board 37 positioned along a plane due to a plurality of positioning snap-fits 116 in the control portion housing 45. As a result, the control board 37 is set up in the control portion housing 45 with the first board portion 91 biased in a direction for bringing it into abutment with the heat sink 38 under a restoring force of the folded portion 93 thereof.

At this time, each of the heat-generating electronic components 41 (the first and second heat-generating electronic component lines 101 and 102) on the first board portion 91 is placed in a state of being biased to each of the component corresponding portions 65 (the first and second component corresponding portions 66 and 67) of the heat sink 38 via the heat dissipation material 42. Further, when the first board portion 91 and the second board portion 92 are disposed in the control portion housing 45 so as to overlap each other via the folded portion 93 using the heat sink 38, the third connector terminals 56 can be easily press-fitted into the third connector terminal connection holes 107 of the first board portion 91 due to the distal-side abutment portion 71 of the heat sink 38, respectively.

Further, the motor terminals 53 can be easily press-fitted into the motor terminal connection holes 108 of the first board portion 91 due to the first and second proximal-side abutment portions 74 and 75 of the heat sink 38, respectively. Further, the first and second connector terminals 54 and 55 can be easily press-fitted into the first and second connector terminal connection holes 105 and 106 of the first board portion 91 due to the first and second intermediate abutment portions 72 and 73 of the heat sink 38, respectively. Then, the heat sink 38 is temporarily fixed to the control portion housing 45 using a plurality of temporarily fixing snap-fits 118. After that the heat sink 38 is permanently fixed to the control portion housing 45 using an adhesive agent or the like.

In this manner, the distal-side abutment portion 71, the first and second intermediate abutment portions 72 and 73, and the first and second proximal-side abutment portions 74 and 75 of the heat sink 38 are just placed on the first board portion 91 in abutment therewith without being individually independently fixed to the first board portion 91 using a screw member or the like. Further, at the time of assembling, the control board 37 is fixed and supported in the control portion housing 45 by press-fitting the third connector terminals 56 into the third connector terminal connection holes 107 of the first board portion 91 of the control board 37, respectively, press-fitting the motor terminals 53 into the motor terminal connection holes 108 of the first board portion 91, respectively, and further pressing-fitting the first and second connector terminals 54 and 55 into the first and second connector terminal connection holes 105 and 106 of the first board portion 91, respectively.

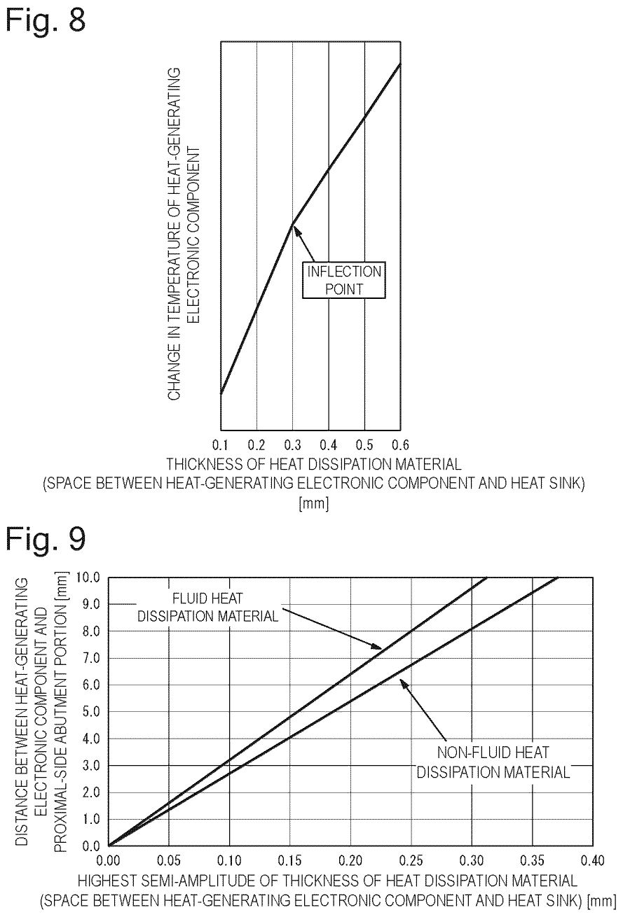

In consideration of the property of the heat dissipation material 42 in the present embodiment, the relationship between the thickness of the heat dissipation material 42 (a space between the heat-generating electronic component 41 and the heat sink 38) and a change in the temperature of the heat-generating electronic component 41 exhibits an inflection point at a point where the thickness of the heat dissipation material 42 is 0.3 mm as indicated in FIG. 8, and it can be understood that the change in the temperature of the heat-generating electronic component 41 can be further effectively suppressed in a region where the thickness of the heat dissipation material 42 is 0.3 mm or thinner.

Further, in consideration of a deformation event (flatness, initial warpage, or the like) of the control board 37 in the present embodiment, the highest semi-amplitude of the thickness of the heat dissipation material 42 and the distance between the heat-generating electronic component 41 and the proximal-side abutment portion 74 or 75 has a relationship characterized as illustrated in FIG. 9 therebetween. Then, it can be understood that, when the clearance between the heat-generating electronic component 41 and the heat sink 38 reduces limitlessly close to zero, the highest semi-amplitude of the thickness of the heat dissipation material 42 is kept no more than 0.15 mm regardless of the type of the heat dissipation material 42 by setting the distance between the heat-generating electronic component 41 and the proximal-side abutment portion 74 or 75 to 4.0 mm or shorter, and therefore the heat dissipation material 42 satisfies the thickness of 0.3 mm or thinner. At this time, the deformation event of the board taken into consideration for the calculation is deformation events “flatness” and “initial warpage” for a non-fluid material while being deformation events “flatness”. “initial warpage”, “thermal strain (thickness deformation)”, and “thermal strain (warpage)” for a fluid material.

Referring to FIG. 1, the rotation-linear motion conversion mechanism 32 is disposed between the bottom portion of the cylinder portion 13 and the piston 18 in the cylinder bore 16 of the cylinder portion 13. The rotation-linear motion conversion mechanism 32 functions to convert the rotational motion input from the speed reduction gear mechanism 31 into a linear motion to provide a thrust force to the piston 18. The rotation-linear motion conversion mechanism 32 includes the spindle 130 and a nut member 131. The rotation from the speed reduction gear mechanism 31 is transmitted to the spindle 130. The nut member 131 is threadedly engaged with this spindle 130. The spindle 130 is non-rotatably connected to an output member (not illustrated) of the speed reduction gear mechanism 31 in the motor/gear housing 28. As a result, the rotational torque can be mutually transmitted between the output member of the speed reduction gear mechanism 31 and the spindle 130.

Referring to FIG. 1, a thrust bearing 136 is disposed between an annular support portion 134 of the spindle 130 and the bottom wall 23 of the cylinder portion 13. The spindle 130 is rotatably supported on the bottom wall 23 of the cylinder portion 13 via this thrust bearing 136. The thrust bearing 136 includes a cylindrical thrust member 138 and a plurality of thrust balls 139. The thrust member 138 is disposed on the bottom wall 23 side of the cylinder portion 13. The thrust balls 139 are rollably disposed between this thrust member 138 and the annular support portion 134 of the spindle 130. A columnar support portion 141 is provided on the spindle 130 on the opposite-end side with respect to the annular support portion 134. An annular groove portion 143 is formed on the outer peripheral surface of the columnar support portion 141. A spring clutch 151, which will be described below, is disposed in this annular groove portion 143.

The nut member 131 is disposed on the radially outer side with respect to an externally threaded portion 145 of the spindle 130. The nut member 131 is cylindrically formed. An internally threaded portion 146 is formed on the inner peripheral surface of the one-end side of the nut member 131. Then, the externally threaded portion 145 of the spindle 130 and the internally threaded portion 146 of the nut member 131 are threadedly engaged with each other. The nut member 131 is supported non-rotatably relative to the piston 18 and thus the cylinder portion 13. This makes the nut member 131 movable along the axial direction according to a rotation of the spindle 130.

The fail-open mechanism 33 is provided on the radially outer side with respect to the nut member 131 in the cylinder bore 16. The fail-open mechanism 33 can release a braking force quickly at the time of, for example, a failure in the power source or the like during braking. The fail-open mechanism 33 includes a fixation member 148, a torque transmission member 149, a torsion spring 150, and the spring clutch 151. The fixation member 148 is generally formed into a cylindrical shape. The nut member 131 is inserted through inside the fixation member 148, and the fixation member 148 and the nut member 131 are restricted from rotating relative to each other. The fixation member 148 is supported non-rotatably relative to the piston 18 and the nut member 131 and thus the cylinder portion 13. An annular protrusion portion 154 is provided at the opposite end of the fixation member 148. The annular protrusion portion 154 protrudes radially outward and annularly. The opposite end of the torsion spring 150 is coupled with this annular protrusion portion 154.

Referring to FIG. 1, the torque transmission member 149 is disposed so as to cover the one-end side of the fixation member 148 with respect to the annular protrusion portion 154 and the annular support portion 134 of the spindle 130 from the radial direction. The torque transmission member 149 is generally formed into a cylindrical shape. One end of the torsion spring 150 is coupled with one end of the torque transmission member 149. Then, the fixation member 148 and the torque transmission member 149 are coupled via the torsion spring 150. An engagement slit portion 156 is provided on the one-end side of the torque transmission member 149. A distal end portion of the spring clutch 151 is engaged with this engagement slit portion 156. A coil portion of the spring clutch 151 is disposed between the annular groove portion 143 provided on the outer peripheral surface of the columnar support portion 141 of the spindle 130 and the torque transmission member 149. The spring clutch 151 functions as a one-way torque limiter that provides rotational resistance only against a rotation of the spindle 130 in one direction (a rotation in a braking direction in the present embodiment).

Then, in the disk brake 1 according to the present embodiment, for example, the detection signal from the detection sensor that responds to a request from the driver or the detection sensor that detects various situations requiring the brake is input to the control board 37 of the electronic control apparatus 36 via the first or second connector 111 or 112 at the time of braking while the vehicle runs normally. Further, for example, the detection signal from the wheel speed detection sensor that detects the wheel speed is input to the control board 37 of the electronic control apparatus 36 via the third connector 113. Further, for example, the detection signal from the rotational angle detector that detects the rotational angle of the rotational shaft of the electric motor 30, and the detection signal from the thrust force sensor that detects the thrust force applied from the inner and outer brake pads 2 and 3 to the disk rotor D are input to the control board 37. Furthermore, power is supplied from a not-illustrated power source device to the control board 37 via the first or second connector 111 or 112.

Subsequently, the control board 37 of the electronic control apparatus 36 actuates the drive unit 9 based on these detection signals. In other words, the rotation of the electric motor 30 in the braking direction is transmitted to the speed reduction gear mechanism 31. Subsequently, the rotation powered up by the speed reduction gear mechanism 31 is transmitted to the rotation-linear motion conversion mechanism 32. When the spindle 130 of the rotation-linear motion conversion mechanism 32 rotates according to the rotation of the speed reduction gear mechanism 31, the nut member 131 threadedly engaged with the spindle 130 advances and moves the piston 18 forward. This piston 18 presses the inner brake pad 2 against the disk rotor D by being moved forward.

Then, due to a reaction force to the pressing force provided from the piston 18 to the inner brake pad 2, the caliper main body 8 moves to the inner side with respect to the carrier 5, thereby pressing the outer brake pad 3 against the disk rotor D with use of each of the claw portions 14 and 14. As a result, a frictional force is generated with the disk rotor D sandwiched between the pair of inner and outer brake pads 2 and 3, and this eventually leads to generation of a braking force on the vehicle.

At the time of this braking, when the spindle 130 rotates in the braking direction, a tightening force exerted by the spring clutch 151 and directed toward the radial center of the spindle 130 (a rotational resistance force between the annular groove portion 143 of the columnar support portion 141 of the spindle 130 and the spring clutch 151) gradually increases. As a result, the torque transmission member 149 rotates in the braking direction via the spring clutch 151 according to the rotation of the spindle 130. Then, due to the rotation of the torque transmission member 149 in the braking direction relative to the fixation member 148, the torsion spring 150 disposed between the torque transmission member 149 and the fixation member 148 is elastically deformed in a torsion direction and stores elastic energy therein.

On the other hand, at the time of braking release, the electric motor 30 rotates in a braking release direction according to an instruction from the control board 37 of the electronic control apparatus 36. Subsequently, the rotation from the electric motor 30 in the braking direction is transmitted to the rotation-linear motion conversion mechanism 32 via the speed reduction gear mechanism 31. As a result, according to the rotation of the spindle 130 of the rotation-linear motion conversion mechanism 32 in the braking release direction, the nut member 131 threadedly engaged with the spindle 130 and the piston 18 are retracted to an initial position, and a predetermined clearance is generated between the inner and outer brake pads 2 and 3 and the disk rotor D and the braking force is released. At the time of this braking release, the rotation of the spindle 130 in the braking release direction is not transmitted to the torque transmission mechanism 149 via the spring clutch 151, but the torque transmission member 149 rotates in the braking release direction to return to the initial position under a restoring force of the torsion spring 150 elastically deformed at the time of braking.

Further, if a failure occurs in the power source or the like and no rotational torque is generated from the electric motor 30 during braking, the fail-open mechanism 33 is actuated. In other words, if the electric motor 30 is not driven normally during braking, the torsion spring 150 elastically deformed at the time of the braking is restored. Then, the torque transmission member 149 rotates in the braking release direction due to the restoring force of the torsion spring 150. Then, the spindle 130 rotates in the braking release direction according to the rotation of the torque transmission member 149 in the braking release direction. As a result, the nut member 131 and the piston 18 are retracted, and the braking force applied by the inner and outer brake pads 2 and 3 to the disk rotor D reduces.

In the above-described disk brake 1 according to the present embodiment, the distal-side abutment portion 71, the first and second intermediate abutment portions 72 and 73, and the first and second proximal-side abutment portions 74 and 75 are provided on the heat sink 38 as the abutment portions 70A in abutment with the first board portion 91 of the control board 37, and the first and second proximal-side abutment portions 74 and 75 are disposed closest to the first and second component corresponding portion lines 66 and 67, i.e., the first and second heat-generating electronic component lines 101 and 102 (each of the heat-generating electronic components 41). Further, preferably, the distance between the first or second proximal-side abutment portion 74 or 75 and each of the heat-generating electronic components 41 is set to 4.0 mm or shorter.

As a result, the disk brake 1 can suppress the influence of the dimensional precision (flatness or the like) of each of the heat-generating electronic components 41 in the first and second heat-generating electronic component lines 101 and 102. Then, the disk brake 1 can reduce a variation in the distance between the heat-generating electronic component 41 and the heat sink 38. i.e., the thickness in the heat dissipation material 42, thereby facilitating thinning management of the heat dissipation material 42. Due to that, the disk brake 1 can ensure excellent heat dissipation efficiency of the heat dissipation material 42, thereby suppressing an increase in the temperature of each of the heat-generating electronic components 41.

For example, in an electronic device disclosed in Japanese Patent Application Laid-open No. 2016-34203 as a conventional technique, a protruding portion provided on a heat sink is in contact with a substrate when the substrate is deformed, but is out of contact with the substrate initially when the electronic device is assembled and an abutment portion is present only at a bolt fixation portion near the outer periphery of the substrate. Therefore, a long distance is generated from electronic components to the abutment portion and a heat dissipating material interposed between the electronic components and the heat sink may be subjected to a reduction in the precision thereof when the electronic device is assembled. As a result, this conventional technique cannot bring about the advantageous effects of the disk brake 1 according to the above-described present embodiment.

Further, in the disk brake 1 according to the present embodiment, each of the heat-generating electronic components 41 is mounted on the surface of the first board portion 91 on the heat sink 38 side, which allows the heat-generating electronic components 41 (the first and second heat-generating electronic component lines 101 and 102) on the first board portion 91 to be kept in a state of being in close contact with the respective component corresponding portions 65 (the first and second component corresponding portions 66 and 67) of the heat sink 38 via the heat dissipation materials 42. As a result, the disk brake 1 can excellently ensure the efficiency of dissipating the heat with the aid of the heat dissipation materials 42 and the heat sink 38. On the other hand, in an electric motor disclosed in Japanese Patent Application Laid-open No. 2008-253049 as a conventional technique, a heat sink is disposed on a board on a non-mounted surface side where no heat-generating electronic component is mounted, and heat from heat-generating electronic components is transmitted to the heat sink via the board, and therefore a large heat dissipation loss occurs. As a result, this conventional technique cannot bring about the advantageous effects of the disk brake 1 according to the above-described present embodiment.

Further, in the disk brake 1 according to the present embodiment, the distal-side abutment portion 71, the first and second intermediate abutment portions 72 and 73, and the first and second proximal-side abutment portions 74 and 75 are provided on the heat sink 38 as the abutment portions 70A in abutment with the first board portion 91 of the control board 37, and these distal-side abutment portion 71, first and second intermediate abutment portions 72 and 73, and first and second proximal-side abutment portions 74 and 75 are in abutment with the first board portion 91 without being fixed to the first board portion 91 using a bolt. As a result, a hole for a screw member, a seat surface for a screw member, and the like do not have to be provided on the first board portion 91 unlike the conventional technique, and the first and second proximal-side abutment portions 74 and 75 of the heat sink 38 can be arranged maximumly close to the first and second component corresponding portion lines 66 and 67, i.e., the first and second heat-generating electronic component lines 101 and 102 (each of the heat-generating electronic components 41).

Furthermore, in the disk brake 1 according to the present embodiment, the motor terminals 53 are located between the first or second proximal-side abutment portion 74 or 75 of the heat sink 38 and the respective heat-generating electronic components 41 on the first board portion 91. In sum, each of the motor terminals 53 is located close to the first or second proximal-side abutment portion 74 or 75 of the heat sink 38. As a result, when the control board 37 and the heat sink 38 are mounted into the control portion housing 45, the motor terminals 53 extending from the electric motor 30 can be precisely and easily press-fitted into the respective motor terminal connection holes 108 of the first board portion 91 without the first board portion 91 deformed with the aid of the first or second proximal-side abutment portion 74 or 75 of the heat sink 38.

Furthermore, in the disk brake 1 according to the present embodiment, each of the motor terminals 53 is located between the first proximal-side abutment portion 74 and the second proximal-side abutment portion 75 of the heat sink 38. As a result, when the control board 37 and the heat sink 38 are mounted into the control portion housing 45, the motor terminals 53 extending from the electric motor 30 can be precisely and easily press-fitted into the respective motor terminal connection holes 108 of the first board portion 91 with the aid of the first and second proximal-side abutment portions 74 and 75 of the heat sink 38.

Furthermore, in the disk brake 1 according to the present embodiment, the control board 37 includes the first board portion 91 and the second board portion 92 formed by folding one long control board into two layers, and the control board 37 is set up in the state of being biased in the direction for placing the first board portion 91 into abutment with the heat sink 38 due to the restoring force of the folded portion 93 of the control board 37 when this control board 37 is mounted in the control portion housing 45. This can ensure that the first board portion 91 of the control board 37 is in contact with the distal-side abutment portion 71, the first and second intermediate abutment portions 72 and 73, and the first and second proximal-side abutment portions 74 and 75 of the heat sink 38, thereby improving the efficiency of dissipating the heat generated from the control board 37 and thus suppressing an increase in the temperature of the control board 37.

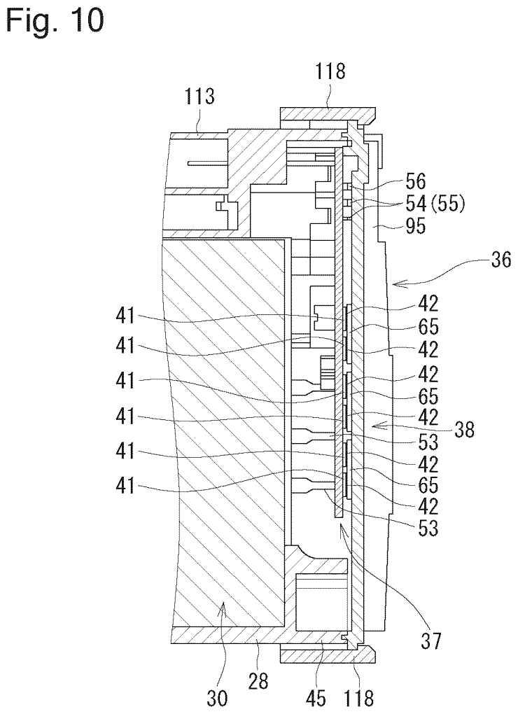

The control board 37 includes the first board portion 91 and the second board portion 92 formed by folding one long control board into two layers in the disk brake 1 according to the present embodiment, but may be configured to simply include one layer as illustrated in FIG. 10.

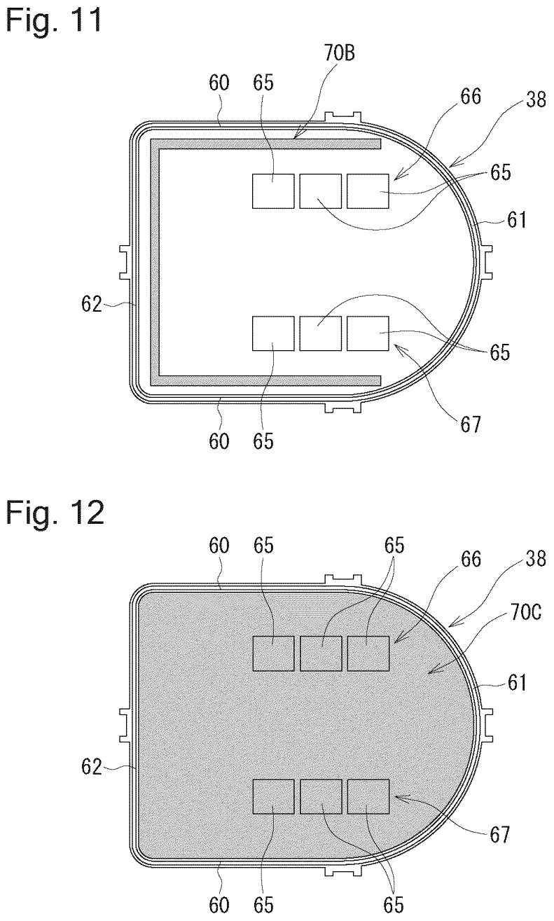

As illustrated in FIG. 11, as an abutment portion 70B provided on the heat sink 38 according to another embodiment, the distal-side abutment portion 71, the first and second intermediate abutment portions 72 and 73, and the first and second proximal-side abutment portions 74 and 75 illustrated in FIG. 5 may be continuously and integrally provided, thereby generating the abutment portion 70B having a squared U-like shape in a planar view (a thin black-filled portion in FIG. 11) so as to surround the first and second component corresponding portion lines 66 and 67 from the main linear portion 62 side. This leads to an increase in the area of the abutment portion 70B and thus contributes to distribution of a stress imposed on the control board 37 in addition to the above-described heat dissipation performance and facilitation of the assembling.

As illustrated in FIG. 12, as an abutment portion 70C provided on the heat sink 38 according to further another embodiment, the abutment portion 70C (a thin black-filled portion in FIG. 12) may be provided on the entire portion of the opposite-end surface of the heat sink 38 except for the first and second component corresponding portion lines 66 and 67 (each of the component corresponding portions 65). This leads to distribution of the stress imposed on the board and also leads to an increase in the volume of the heat sink 38, thereby contributing to an increase in the heat mass and further improvement of the heat dissipation performance, in addition to the facilitation of the assembling.

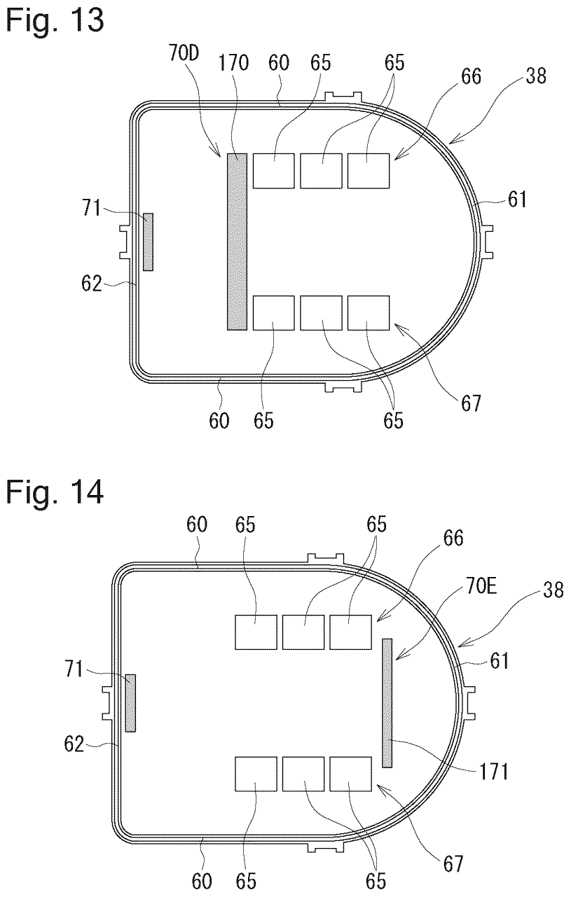

As illustrated in FIG. 13, as an abutment portion 70D provided on the heat sink 38 according to further another embodiment, a proximal-side abutment portion 170 (a thin black-filled portion in FIG. 13) may be provided so as to extend from the first and second component corresponding portion lines 66 and 67 of the heat sink 38 toward the main linear portion 62 side perpendicularly to the first and second component corresponding portion lines 66 and 67 in addition to the distal-side abutment portion 71 (a thin black-filled portion in FIG. 13). This causes the proximal-side abutment portion 170 to be partially located between the first and second component corresponding portion lines 66 and 67 of the heat sink 38, i.e., the first and second heat-generating electronic component lines 101 and 102 (each of the heat-generating electronic components 41) of the first board portion 91, and the distal-side abutment portion 71 as a result thereof. This makes it easy to lay out electronic components on the outer peripheral portion of the first board portion 91 of the control board 37 in addition to the above-described heat dissipation performance and facilitation of the assembling.

As illustrated in FIG. 14, as an abutment portion 70E provided on the heat sink 38 according to further another embodiment, a proximal-side abutment portion 171 (a thin black-filled portion in FIG. 14) may be provided so as to extend from the first and second component corresponding portion lines 66 and 67 of the heat sink 38 toward the curved portion 61 side perpendicularly to the first and second component corresponding portion lines 66 and 67 in addition to the distal-side abutment portion 71 (a thin black-filled portion in FIG. 14). This causes the first and second component corresponding portion lines 66 and 67 of the heat sink 38, i.e., the first and second heat-generating electronic component lines 101 and 102 (each of the heat-generating electronic components 41) of the first control board 91 to be located between the proximal-side abutment portion 171 and the distal-side abutment portion 71 as a result thereof. The proximal-side abutment portion 171 and the distal-side abutment portion 71 are located on both the right side and the left side of the first and second component corresponding portion lines 66 and 67 of the heat sink 38, i.e., the first and second heat-generating electronic component lines 101 and 102 of the first board portion 91, respectively, in this manner, by which a variation in the thickness of the heat dissipation materials 42 corresponding to the plurality of heat-generating electronic components 41 can be reduced.

The present invention shall not be limited to the above-described embodiments, and includes various modifications. For example, the above-described embodiments have been described in detail to facilitate a better understanding of the present invention, and the present invention shall not necessarily be limited to the configuration including all of the described features. Further, a part of the configuration of some embodiment can be replaced with the configuration of another embodiment. Further, some embodiment can also be implemented with a configuration of another embodiment added to the configuration of this embodiment. Further, each embodiment can also be implemented with another configuration added, deleted, or replaced with respect to a part of the configuration of this embodiment.

The present application claims priority under the Paris Convention to Japanese Patent Application No. 2021-207112 filed on Dec. 21, 2021. The entire disclosure of Japanese Patent Application No. 2021-207112 filed on Dec. 21, 2021 including the specification, the claims, the drawings, and the abstract is incorporated herein by reference in its entirety.

### REFERENCE SIGNS LIST

1 disk brake (electric brake apparatus)
2 inner brake pad (frictional pad)
3 outer brake pad (frictional pad)
30 electric motor
36 electronic control apparatus
37 control board (board)
38 heat sink
41 heat-generating electronic component (electronic component)
42 heat dissipation material
53 motor terminal
54 first connector terminal
55 second connector terminal
56 third connector terminal
70A to 70E abutment portion
71 distal-side abutment portion
72 first intermediate abutment portion
73 second intermediate abutment portion
74 first proximal-side abutment portion
75 second proximal-side abutment portion
91 first board portion
92 second board portion
100 first heat-generating electronic component line
101 second heat-generating electronic component line
D disk rotor (rotor)

1. An electronic control apparatus comprising:
a board;
an electronic component mounted on the board; and
a heat sink provided with a heat dissipation material interposed between the heat sink and the electronic component,
wherein the heat sink includes at least
a distal-side abutment portion in abutment with the board at a position away from the electronic component, and
a proximal-side abutment portion in abutment with the board without being fixed to the board at a position away from the electronic component by a distance shorter than a distance between the electronic component and the distal-side abutment portion.

2. The electronic control apparatus according to claim 1, wherein the distal-side abutment portion is in abutment with the board without being fixed to the board.

3. The electronic control apparatus according to claim 1, wherein the board is fixed by a terminal.

4. The electronic control apparatus according to claim 1, wherein a terminal is disposed between the electronic component and the proximal-side abutment portion.

5. The electronic control apparatus according to claim 4, wherein the terminal is a motor terminal of an electric motor.

6. The electronic control apparatus according to claim 1, wherein the proximal-side abutment portion is provided at each of two portions, and
wherein a terminal is disposed between a first proximal-side abutment portion and a second proximal-side abutment portion.

7. The electronic control apparatus according to claim 1, wherein the proximal-side abutment portion is disposed between the electronic component and the distal-side abutment portion.

8. The electronic control apparatus according to claim 1, wherein the electronic component is disposed between the proximal-side abutment portion and the distal-side abutment portion.

9. The electronic control apparatus according to claim 1, wherein the distal-side abutment portion and the proximal-side abutment portion are continuously and integrally provided.

10. The electronic control apparatus according to claim 1, wherein the board includes a first board portion and a second board portion, the second board portion being folded from the first board portion and disposed so as to face the first board portion,
wherein the electronic component is mounted on the first board portion, and
wherein the board is set up in a state that the first board portion is biased to the heat sink side.

11. The electronic control apparatus according to claim 1, wherein the heat dissipation material is a non-fluid material or a fluid material.

12. An electric brake apparatus comprising:
an electric motor configured to provide power for pressing a frictional pad against a rotor that rotates together with a wheel; and
an electronic control apparatus configured to control driving of the electric motor,
wherein the electronic control apparatus includes
a board,
an electronic component mounted on the board, and
a heat sink provided with a heat dissipation material interposed between the heat sink and the electronic component, and
wherein the heat sink includes at least
a distal-side abutment portion in abutment with the board at a position away from the electronic component, and
a proximal-side abutment portion unfixedly provided in abutment with the board at a position away from the electronic component by a distance shorter than a distance between the electronic component and the distal-side abutment portion.

13. The electric brake apparatus according to claim 12, wherein the distal-side abutment portion is unfixedly in abutment with the board.
